(19) United States
(12) Patent Application Publication
(10) Pub. No.: US 2013/0287402 A1
(43) Pub. Date: Oct. 31, 2013

(54) OPTICAL RECEIVER IMPLEMENTED WITH SEMICONDUCTOR OPTICAL AMPLIFIER IN FRONT END THEREOF AND METHOD TO CONTROL THE SAME

(71) Applicant: SUMITOMO ELECTRIC INDUSTRIES, LTD., Osaka (JP)

(72) Inventor: Hirotaka OOMORI, Yokohama-shi (JP)

(73) Assignee: SUMITOMO ELECTRIC INDUSTRIES, LTD., Osaka (JP)

(21) Appl. No.: 13/868,370

(22) Filed: Apr. 23, 2013

(30) Foreign Application Priority Data
Apr. 27, 2012 (JP) 2012-102050

(51) Int. Cl. H04B 10/69; H01S 5/068

(52) U.S. Cl. CPC H04B 10/6911; H01S 5/06804
USPC 398/93; 359/337

(57) ABSTRACT

An optical receiver implemented with a semiconductor amplifier (SOA) whose temperature is controlled by the automatic temperature control (ATC) circuit is disclosed. The optical receiver further includes an optical de-multiplexer, optical devices, a signal processor, and a controller. The controller monitors a temperature of the SOA and time derivatives thereof. The controller activates the optical devices and the signal processor after the time derivative of the temperature of the SOA becomes less than a reference.

### BACKGROUND OF THE INVENTION

1. Field of the Invention

The present invention relates to an optical receiver implementing with a semiconductor optical amplifier (SOA) in the front end thereof, and a method to control the SOA.

2. Related Background Arts

As an explosive increase in a size of data transmitted on a network system, the speed of the network system continuously increases and devices installed in the system, such as an optical transceiver, are requested to operate faster and faster. The transmission speed of the network exceeds 10 Gbps and reaches 40 Gbps or 100 Gbps, which forces devices used therein unable to follow such a transmission speed as a single element. One solution is the wavelength division multiplexing system.

For instance, the transmission speed of 100 Gbps multiplexes four (4) signals each having a specific wavelength different from others in a wavelength band of 1300 nm and a speed of 25 Gbps; then the total transmission speed realizes 100 Gbps. In an optical receiver, an optical signal is de-multiplexed into four sub-signals depending on the wavelengths. Such an optical receiver often implements with an SOA in the front end thereof to compensate optical loss caused in the transmission medium, namely, an optical fiber coupling an optical transmitter with the optical receiver. However, an SOA in the optical gain thereof usually depends on a temperature and a bias current supplied thereto. In particular, in the start-up of the optical receiver accompanied with the SOA, the optical gain of the SOA is necessary to be controlled precisely.

### SUMMARY OF THE INVENTION

An aspect of the present application relates to an optical receiver that includes an SOA in the front end thereof, an optical de-multiplexer, a plurality of optical devices, a signal processor, and a controller. The SOA receives an optical signal and outputs an amplified optical signal that contains a plurality of signals each of which has a wavelength different from others. The optical de-multiplexer de-multiplexes the amplified optical signal into de-multiplexed optical signals depending on the wavelength. Each of the optical devices converts the de-multiplexed optical signal into an electrical signal. The signal processor recovers data contained in the electrical signals and extracts a clock contained in at least one of electrical signals. A feature of the optical receiver is that the controller activates the optical devices and the signal processor after the SOA stabilizes a temperature thereof in a target temperature.

The controller of an embodiment decides the stabilization of the temperature of the SOA whether a time derivative of the temperature in an absolute thereof becomes less than the first reference. The controller further evaluates how the temperature of the SOA becomes close to the target temperature. When the temperature of the SOA becomes close to the target temperature, specifically, a difference between the current temperature of the SOA and the target temperature becomes less than the second reference.

Another aspect of the present application relates to a method to control an SOA installed on a thermo-electric-cooler (TEC). The method includes steps of: monitoring a current temperature of the SOA through a temperature sensor put on the TEC; calculating a time derivative of the temperature of the SOA by subtracting a previous temperature monitored previously from the current temperature; and supplying a bias current to eh SOA after the time derivative of the temperature of the SOA becomes less than a preset reference.

### BRIEF DESCRIPTION OF DRAWINGS

The foregoing and other purposes, aspects and advantages will be better understood from the following detailed description of a preferred embodiment of the invention with reference to the drawings, in which:

FIG. 1 shows a functional block diagram of an optical receiver according to an embodiment of the present invention;

FIG. 2 shows a functional block diagram of a controller implemented with the optical receiver shown in FIG. 1;

FIG. 3 shows a typical relation of a bit-error-rate (BER) against optical input power;

FIG. 4 shows a typical behavior of an optical gain of an SOA against a bias current supplied thereto for various temperatures; and

FIG. 5 shows time variations of the temperature of the SOA and the time derivative thereof for two initial conditions between the current temperature and the target temperature.

### DESCRIPTION OF PREFERRED EMBODIMENTS

In a comparable arrangement of an optical receiver implemented with an SOA, the SOA and devices put in the downstream of the SOA starts the operation thereof substantially at the same time. The SOA is supplied with the bias current at the start-up and controlled in the temperature thereof also at the start-up. However, the SOA promptly responds to a change of the bias current, but the stabilization of the temperature thereof is usually delayed from the change of the bias current. When the un-stabilized temperature of the SOA is lower than the target temperature but the SOA is provided with the preset bias current, the optical gain of the SOA becomes enough high. On the other hand, the un-stabilized temperature is higher than the target one, the SOA does not show the preset optical gain and the optical output thereof becomes smaller than the designed one.

Accordingly, in the comparable arrangement of the optical receiver, the optical devices occasionally receives optical signals with excess power in the former occasion, or, the optical power becomes far less than the designed level in the latter case. Then, the signal processor put downstream of the optical devices is unable to recover data exactly and to extract the clock stably, both of which are contained in the optical signals.

Next, some preferred embodiments according to the present invention will be described as referring to drawings.

In the description of the drawings, numerals or symbols same or similar to each other will refer to elements same or similar to each other without overlapping explanations.

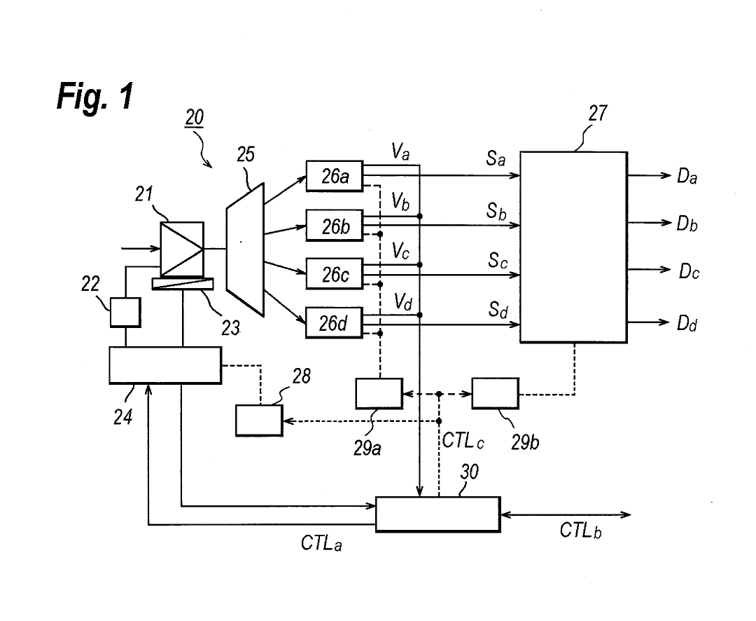

FIG. 1 shows a functional block diagram of an optical receiver 20 according to an embodiment of the present invention. The optical receiver 20 primarily includes an SOA 21, an optical de-multiplexer 25, a plurality of light-receiving devices, 26a to 26d, and a signal processor 27. The optical receiver 20 further includes a controller 30 and several power supplies, 28, 29a, and 29b.

The optical receiver 20 of the embodiment shown in FIG. 1 includes four (4) light-receiving devices corresponding to signals contained within the incoming optical signal. However, the number of the optical receiver 20 is not restricted to four (4); two (2), six (6), eight (8) or more devices are realizable in an optical receiver.

Moreover, the embodiment shown in FIG. 1 has the total transmission speed of 100 Gbps, namely, each of the optical devices may receive the signal with the transmission speed of 25 Gbps, then, the total of 100 Gasp transmission speed is available by multiplexing/de-multiplexing these four (4) signals. Each of four (4) signals has a characteristic wavelength in the 1300 nm band, for instance, 1295 nm, 1300 nm, 1304 nm, and 1309 nm, respectively.

The optical receiver 20, as previously described, includes the SOA 21 driven by a current source 22 and a thermo-electric cooler (hereafter denoted as TEC) 23 in the temperature thereof under a control of the SOA driver 24. The SOA 21, for instance, placed on the TEC 23 with a temperature sensor, not explicitly illustrated in FIG. 1. The SOA driver 24 keeps the temperature of the TEC 23 in a target temperature as sensing the temperature thereof by a temperature sensor placed immediately close to the SOA 21 on the TEC 23, which is called as the automatic temperature control (ATC).

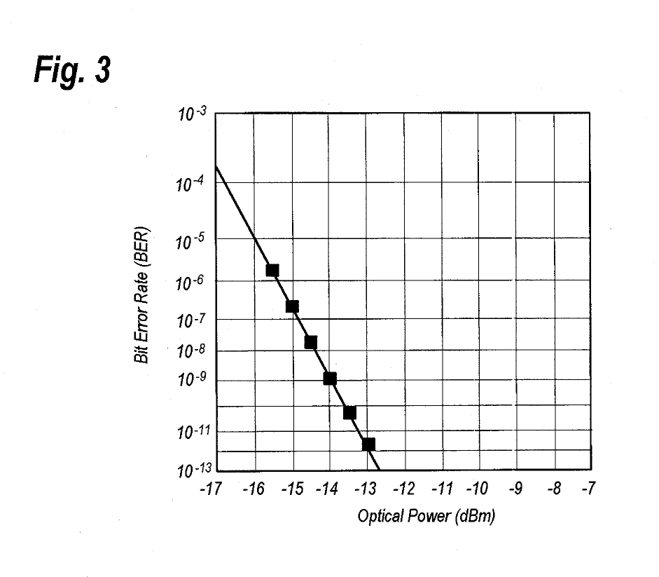

The SOA 21 compensates the optical loss caused in the transmission medium. FIG. 3 shows atypical sensitivity of the optical receiver where the bit error rate (BER) in the vertical axis is denoted against the optical input power in the horizontal axis thereof. The BER of 10⁻¹², which may be an index for the transmission quality, is obtained for the input power of −13 dBm for the optical device 26. Considering the optical loss of 1.5 dB caused in the optical de-multiplexer 25 set in the downstream of the SOA 21, then, the optical signal input to the optical de-multiplexer 25 is necessary to show the optical power of −11.5 dBm for respective wavelengths. On the other hand, the IEEE standard for the optical transmission system defines that the optical input power for the optical receiver is −23.0 dBm in the minimum. Accordingly, the SOA 21 needs to have the minimum gain of 11.5 dB.

The SOA 21 is controlled in the optical gain thereof by adjusting the bias current supplied thereto from the current source 22. When the optical power output from the

SOA 21 is insufficient, the bias current is increased to enhance the optical gain of the SOA 21; while, the output power of the SOA 21 is excessive, the bias current is reduced.

The SOA 21 also varies the optical gain thereof depending on a temperature thereof. In the present embodiment, a thermo-electric cooler (TEC) 23 typically a Pelitier device controls the temperature of the SOA 21 to be substantially equal to, for instance, 25° C. The SOA driver 24 drives the current source 22 and the TEC 23 in the present embodiment; and this SOA driver 24 is controlled by the controller 30.

The optical de-multiplexer 25 receives the output of the SOA 21 to de-multiplex it into four (4) de-multiplexed signals, each of which are directed to respective optical devices, 26a to 26d. Each of optical devices, 26a to 26d, includes a light-receiving device, typically a photodiode, to convert respective de-multiplexed signals into electrical signals, Sa to Sd. The optical devices, 26a to 26d, also output monitoring signals, Va to Vd, each corresponding to an optical input power of respective de-multiplexed signals.

Each of electrical signals, Sa to Sd, enters the signal processor 27 that recovers respective data and extracts a clock from the electrical signals. The signal processor 27 of the present embodiment includes four (4) data recovery corresponding to respective optical devices, 26a to 26d, and at least one clock extractor. The recovered data, Da to Dd, are output from the signal processor 27 to process them further in the system set in the downstream of the optical receiver 20.

The first power supply 28 controls the SOA 21 and the periphery thereof, the second power supply 29a drives the optical devices, 26a to 26d, while, the third power supply 29b controls the signal processor 27. These power supplies, 28 to 29b, are controlled from the controller 30, in particular, the start-up thereof are instructed by the controller 30.

Next, an operation of the optical receiver 20 described above will be described. In particular, the start-up of the optical receiver 20 will be described in detail.

As the start-up of the optical receiver 20, a time becomes longer for the temperature of the SOA 21 to be set in a target temperature of, for instance, 25° C. in an example as a difference between an initial temperature and the target temperature above described is larger. On the other hand, the adjustment of the bias current for the SOA 21 is promptly completed to set the optical gain of the SOA 21 necessary to the optical receiver 20 compared with the adjustment of the temperature.

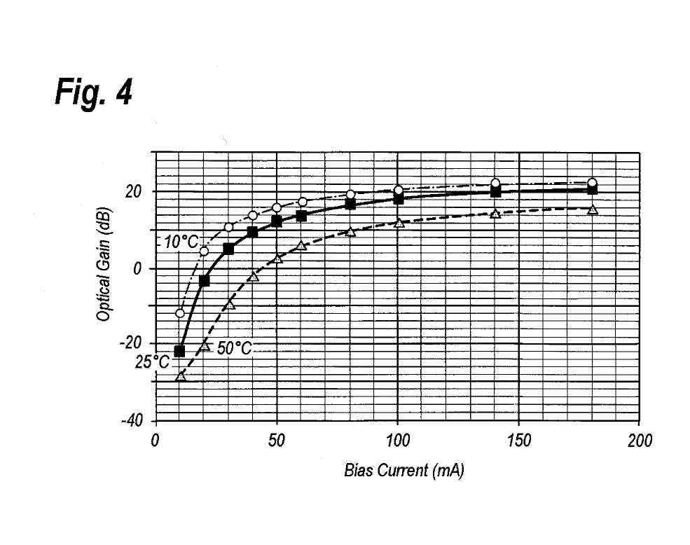

FIG. 4 shows the optical gains of the SOA 21 against the bias current supplied thereto as varying the temperature of the SOA 21, where the optical gain in the vertical axis corresponds to the one optical signal when four optical signals are input to the SOA 21. For the bias current of 60 mA in FIG. 4, the SOA 21 shows the gain of 6 dB at the temperature of 50° C., while, the gain increases to 12.6 dB for the temperature of 25° C. The condition of the temperature of 25° C. exceeds the necessary optical gain of 11.5 dB, which brings the qualified conversion from the optical signal into the electrical signal. While, the SOA 21 shows the optical gain of only 6 dB at the temperature of 50° C., which is insufficient over 5 dB to satisfy the minimum input power for the optical device, 26a to 26d. That is, when the optical signal input to the optical receiver 20 has the minimum power of −23 dBm in the IEEE standard, the optical input power for the optical device becomes only −18.5 (=−23+6−1.5) dBm, which is less than the necessary power of −13 dBm for the optical device by 5.5 dB.

The optical device, 26a to 26d, receives the optical signal with the power of −18.5 dBm whose BER becomes only about 10⁻³ asshown in FIG. 3, which brings enough poor quality in the conversion of the optical signal into the electrical signal, Sa to Sd, and sends thus converted electrical signals to the signal processor 27. The signal processor 27 recovers data, Da to Dd, and extracts the clock from those data with poor quality. Then the recovery of the data and the extraction of the clock often become inaccurate and instable.

For the SOA 21, referring to FIG. 4, the optical gain thereof becomes stable with respect to the bias condition and independent of the temperature thereof in conditions where the bias current is relatively larger. The embodiment of the present invention positively utilizes this characteristic of an SOA to start-up the optical receiver promptly.

For instance, the optical gain of an SOA is 19 dB at 10° C., while, it becomes 17 dB at 25° C., which is comparable to the gain at 10° C., under the bias current of 80 mA. In respective temperatures, the optical device, 26a to 26d, receives the de-multiplexed optical signal with the power of −5.5 dBm and −7.5 dBm for the temperature of 10° C. and 25° C., respectively, whne the optical signal with the minimum power of −23 dBm is input to the optical receiver 20. Then, both conditions exceed the necessary power of −13 dBm for the optical device. In such a case, the possibility to cause the miss-recovery of the data and miss-extraction of the cock becomes ignorable.

The optical receiver 20 of the present embodiment supplies the bias current to the SOA 21 after the temperature of the SOA 21 becomes stable. Specifically, when the temperature of the SOA 21 in the time derivative thereof becomes less than preset level, then the optical devices, 26a to 26d, and the signal processor 27 are activated. That is, respective units in the optical receiver 20, namely, the SOA 21, the optical devices, 26a to 26d, and the signal processor 27 are sequentially activated with a preset lag to start-up the optical receiver 20 promptly.

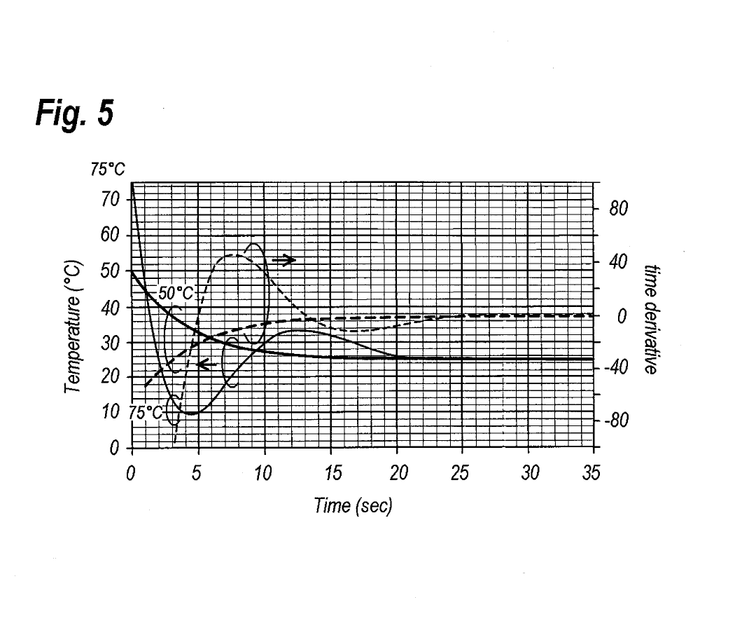

FIG. 5 shows the temperatures of the SOA 21 and the time derivatives thereof for the target temperature of 25° C. when the initial temperature is 50° C. and 75° C., respectively. When the initial temperature is 50° C., the temperature of the SOA 21 gradually decreases to the target temperature, and stabilizes after 10 seconds from the start-up. On the other hand, the temperature of the SOA 21 iterates some undershoots and overshoots for the initial temperature of 70° C. and needs about 20 seconds till the stabilization.

In FIG. 5, broken lines correspond to the time derivatives of the temperature of the SOA 21. The temperature of the SOA 21 becomes stable as the time derivatives thereof are close to zero. FIG. 5 shows that the time necessary to stabilize the temperature of the SOA 21 at the preset temperature, namely, the period until the time derivatives of the temperature in an absolute thereof becomes less than a preset level, depends on a difference between the initial temperature and the target temperature. Moreover, the period till the temperature stabilizes is probably estimated from the initial time derivatives of the temperature, which means that a look-up-table defining periods to stabilize the temperature of the SOA against initial temperatures are unnecessary.

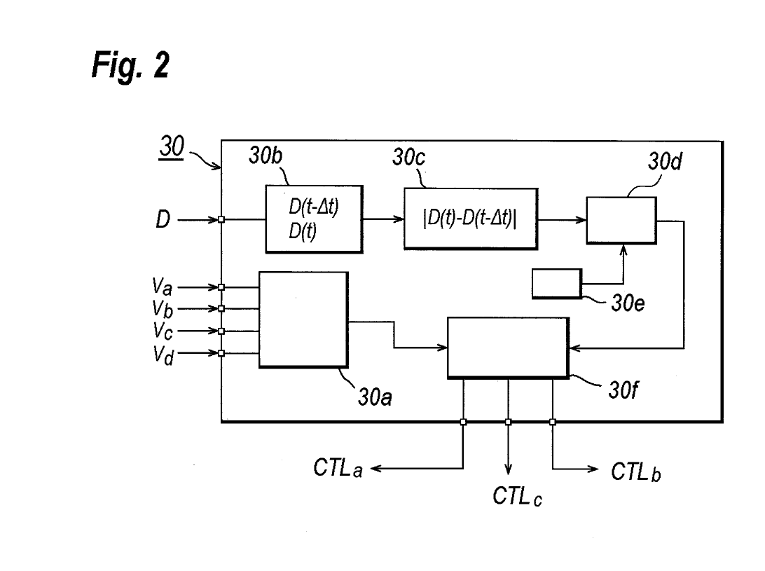

FIG. 2 shows a functional block diagram of the controller 30. The controller 30 primarily includes a first register 30a, a second register 30b, an arithmetical unit 30c, and a comparator 30d. The first register 31 temporarily holds the optical levels, Va to Vd, each output from the optical devices, 26a to 26d. The bias current supplied to the SOA 21 from the current source 22 is controlled based on these output levels, Va to Vd, through the interface 30f.

The second register 30b not only holds a data corresponding to the current temperature T_{SOA}(t) of the SOA 21 but a temperature sensed previously T_{SOA} (t-Δt). The arithmetical unit 30c calculates the time derivative of the temperature ΔT_{SOA} of the SOA 21 based on two data, T_{SOA}(t) and T_{SOA} (t-Δt), each held in the second register 30b; that is:

ΔT_{SOA}=T_{SOA} (t)−T_{SOA} (t−Δt),

where Δt denotes a sampling period of the temperature of the SOA 21 and typically set from several tenses to several hundreds of milli-seconds.

The time derivative thus calculated denotes how the temperature of the SOA 21 stabilizes. When the time derivative becomes less than the preset level, the controller 30 decides that the temperature of the SOA 21 stabilizes, and instructs the power supplies, 29a and 29b, to activate the optical devices, 26a to 26d, and the signal processor 27.

The operation of the optical receiver 20 will be described as referring to FIGS. 1 and 2. First, the host system instructs the optical receiver 20 to start-up or to wake up from the sleep mode. The controller 30 thus instructed from the host system activates the power supply 28 for the SOA 21 and the peripheries, 22 to 24, thereof. The SOA 21, the current source 22, the TEC 23 and the SOA driver 24 are activated. As explained above, the bias current for the SOA 21 is set to be a predetermined level at which the SOA 21 in the optical gain thereof becomes substantially independent of the temperature. The SOA driver 24 starts to control the temperature of the SOA 21 to become the preset temperature. During the initial process above, the second power supplies, 29a and 29b, are slept not to activate the optical devices, 26a to 26d, and the signal processor 27. Accordingly, the signals corresponding to the optical levels for respective optical devices, 26a to 26d, are undefined and meaningless.

The SOA 21 is controlled in the temperature thereof to be substantially equal to the target temperature by a feedback loop of the temperature sensor set on the TEC 23 immediately close to the SOA 21, the SOA driver 24 and the TEC 23, which is often called as the automatic temperature control (ATC). The output of the temperature sensor is concurrently sent to the controller 30 through the SCA driver 24 and stored in the second register 30b.

The second register 30b sequentially holds the current temperature T_{SOA}(t) and that previous temperature T_{SOA}(t−Δt). Next, the arithmetical unit 30c calculates the time derivative of the temperature by two data, T_{SOA}(t) and T_{SOA}(t−Δt). The comparator 30d compares thus calculated time derivative, |T_{SOA}(t)-T_{SOA}(t−Δt)|Δt, with the preset reference.

When the time derivative becomes less than the preset reference, the temperature of the SOA 21 is regarded to become close to the target temperature, or the optical gain of the SOA 21 substantially becomes independent of the temperature under the bias current presently supplied thereto as shown in FIG. 4. That is, the SOA 21 in the optical gain thereof becomes stable independent of the temperature and the output of the SOA 21 is secured to be an enough level for respective optical devices, 26a to 26d. Then, the controller 30 starts the power supplies, 29a and 29b, to power the optical devices, 26a to 26d, and the signal processor 27.

When the initial temperature is apart from the target temperature of the SOA 21, the control of the temperature of the SOA 21 often accompanies with the overshoots and undershoots, as shown in FIG. 5, and the time derivative thereof becomes small enough as shown in FIG. 5 depending on the sensing period in spite of the temperature of the SOA 21 apart from the target one, specifically, when the temperature becomes extrema of the undershoots and overshoots. In such a case, the current temperature of the SOA 21 T_{SOA}(t) should be compared with the target one and compare the difference therebetween |T_{SOA} (t)−T_{SOA}^{(target)}| with a reference. In another algorithm to decide the convergence of the temperature is, the controller 30 may calculate the time derivative of the temperature by a twice period 2t. That is, the second register 30b holds the temperature sensed at an instant of t−2Δt and calculates the time derivative by two data of T_{SOA} (t) and T_{AO} (t−2Δt). When thus calculated time derivative becomes less than the preset reference, the controller decides that the temperature of the SOA 21 stabilizes at the target temperature or becomes a condition where the optical gain of the SOA 21 becomes substantially independent of the temperature.

Although the embodiment above described assumes that the temperature of the SOA 21 is sensed by a temperature sensor set immediately close to the SOA 21 on the TEC 23; the controller is able to decide the convergence or the stabilization of the temperature of the SOA 21 through the current provided from the SOA driver 24 to drive the TEC 23. That is, as the temperature of the TEC 23 approaches the target temperature, the driving current for the TEC 23 gradually becomes stable, namely, a time derivative thereof becomes small enough. Accordingly, the controller 30 acknowledges the stabilization of the temperature of the SOA 21 through the driving current of the TEC 23.

The optical receiver 20 thus described does not provide the electrical power to the optical devices, 26a to 26d, and the signal processor 27 until the temperature of the SOA 21 substantially stabilizes at the target temperature. Accordingly, the optical devices do not output signals, Sa to Sd, and the monitored levels, Va to Vd, and the signal processor 27 does not recover the data and extract the clock. The signal processor 27 starts to recover the data and extract the clock after the temperature of the SOA 21 stabilizes and the optical devices, 26a to 26d, receive de-multiplexed optical signals with enough power.

The temperature of the SOA 21 is occasionally in the target temperature in the start-up thereof to show the sufficient optical gain and the de-multiplexed optical signals with excess power enter the optical devices, 26a to 26d. Even in such a case, the optical devices, 26a to 26d, are not activated by the power supply 29a, which protects the optical devices, 26a to 26d.

In the foregoing detailed description, the method and apparatus of the present invention have been described with reference to specific exemplary embodiments thereof. It will, however, be evident that various modifications and changes may be made thereto without departing from the broader spirit and scope of the present invention. The present specification and figures are accordingly to be regarded as illustrative rather than restrictive.

I claim:

1. An optical receiver, comprising:
a semiconductor optical amplifier (SOA) configured to receive an optical signal and output an amplified optical signal, the optical signal containing a plurality of signals each having a wavelength specific thereto and different from others;
an optical de-multiplexer configured to de-multiplex the amplified optical signal into a plurality of de-multiplexed optical signals depending on the wavelength thereof;
a plurality of optical devices configured to convert de-multiplexed optical signals into electrical signals;
a signal processor configured to recover data contained in the electrical signals and to extract a clock contained in at least one of electrical signals; and
a controller configured to activate the optical devices and the signal processor after the SOA stabilizes a temperature thereon in a target temperature.

2. The optical receiver of claim 1,
wherein the controller includes a first register, an arithmetical unit, and a comparator, the first register holding a current temperature of the SOA and a previous temperature of the SOA sensed previously by a preset period, the arithmetical unit calculating a time derivative of the temperature of the SOA by subtracting the previous temperature from the current temperature, the comparator comparing the time derivative with a first preset reference, and
wherein the controller decides the temperature of the SOA becomes stable when the time derivative of the temperature of the SOA becomes less than the first preset reference.

3. The optical receiver of claim 2,
wherein the comparator further arithmetical unit further calculates a difference between the current temperature of the SOA and a target temperature, and
wherein the controller decides the temperature of the SOA becomes stable when the difference is less than a second preset reference.

4. The optical receiver of claim 2,
wherein the first register further holds a past temperature of the SOA sensed in past before the preset period, the arithmetical unit further calculating another time derivative of the temperature of the SOA by subtracting the past temperature from the current temperature, and
wherein the controller decides the temperature of the SOA becomes stable when the another time derivative of the temperature of the SOA becomes less than a third preset reference.

5. The optical receiver of claim 1,
wherein the SOA is supplied with a bias current after the controller decides that the temperature of the SOA becomes stable.

6. The optical receiver of claim 5,
wherein the bias current has a magnitude for the SOA to have an optical gain substantially independent of the temperature thereof.

7. The optical receiver of claim 1,
further comprising a thermo-electric cooler (TEC) for controlling the temperature of the SOA,
wherein the TEC is controlled by the controller.

8. The optical receiver of claim 7,
further including a temperature sensor to sense the temperature of the SOA and an SOA driver to drive the TEC and a bias current supplied for the SOA to adjust an optical gain thereof,
wherein the temperature sensor is set immediately close to the SOA on the TEC, and the temperature sensor, the TEC, and the SOA driver comprises an automatic temperature control (ATC) loop.

9. The optical receiver of claim 7,
wherein the controller decides whether the temperature of the SOA becomes stable by monitoring a driving current supplied to the TEC.

10. A method for controlling a semiconductor optical amplifier (SOA) installed on a thermo-electric cooler (TEC), comprising a steps of:
monitoring a current temperature of the SOA through a temperature sensor put on the TEC;
calculating a time derivative of the temperature of the SOA by subtracting a previous temperature monitored previously from the current temperature;
supplying a bias current to the SOA after the time derivative of the temperature of the SOA monitored through the temperature sensor becomes less than a preset reference.

11. The method of claim 10,
further comprising steps of, after the calculation of the time derivative, calculating another time derivative of the temperature of the SOA by subtracting a past temperature monitored before monitoring the previous temperature from the current temperature;
wherein the step of supplement of the bias current includes a step to compare the another time derivative of the temperature and to supply the bias current when the time derivative of the temperature of the SOA becomes less than the preset reference and the another time derivative of the temperature of the SOA becomes less than another reference.

12. The method of claim 10,
wherein the bias current supplied to the SOA has a magnitude by which the SOA shows an optical gain thereof substantially independent of the temperature.

13. The method of claim 12,
further including a step, after the supplement of the bias current, activating a device put in downstream of the SOA.
